(19) United States
(12) Patent Application Publication
(10) Pub. No.: US 2025/0301602 A1
(43) Pub. Date: Sep. 25, 2025

(54) LIQUID COOLING CABINET

(71) Applicant: XI'AN YEP TELECOM TECHNOLOGY CO., LTD., Shaanxi (CN)

(72) Inventors: LI ZHU, Shaanxi (CN); KE ZHOU, Shaanxi (CN); JINBIAO JI, Shaanxi (CN)

(21) Appl. No.: 18/868,875

(22) PCT Filed: Jul. 20, 2023
(86) PCT No.: PCT/CN2023/108452

§ 371 Date: Nov. 25, 2024

(30) Foreign Application Priority Data
Sep. 26, 2022 (CN) 202211176173.X

(51) Int. Cl. H05K 7/20; H05K 5/02

(52) U.S. Cl. CPC H05K 7/20327; H05K 5/0247; H05K 7/203

(57) ABSTRACT

A liquid cooling cabinet includes a cabinet body, an independent compartment, and a connector. The cabinet body includes an accommodating space having an opening. The cabinet body further includes a bottom plate and side plates. The opening corresponds to the bottom plate. The bottom plate is provided with a liquid inlet pipe. The independent compartment is located in the accommodating space. The independent compartment has a device accommodating cavity. The connector is in communication with the liquid inlet pipe and the device accommodating cavity. The connector is located in the accommodating space. The connector includes a first connecting member and a second connecting member. The first connecting member is disposed in the liquid inlet pipe. The second connecting member is disposed in the independent compartment. The first connecting member is detachably connected to the second connecting member.

### BACKGROUND

### 1. Technical Field

The present application relates to the technical field of cooling technology, and specifically relates to a liquid cooling cabinet.

### 2. Background of the Invention

In the big data era, more and more enterprises in the finance, communication, electric power industries and the like start to establish their own data centers to meet the increasingly severe data and service challenges from users. There are a large number of internet technology (IT) devices in a data center. For example, the IT device may be a server, a switch, a router, or any other critical electronic device. The IT devices generate a significant amount of heat during operation.

A liquid cooling cabinet is a cabinet for cooling an IT device by liquid cooling. Liquid cooling can take most of the heat away through a coolant liquid, thereby realizing the technology of heat dissipation and cooling. Immersion liquid cooling is a commonly used cooling technique in liquid cooling. By means of immersion liquid cooling, the coolant liquid can fully cover the entire IT device to achieve a cooling effect of uniform heat exchange.

In the existing art, a plurality of IT devices are all placed inside the liquid cooling cabinet. Each IT device can be completely immersed into the coolant liquid. The liquid cooling cabinet is typically configured with an upper cover. During heat dissipation and cooling of the IT device by the coolant liquid, a gaseous coolant is present between a level of the coolant liquid in the liquid cooling cabinet and the upper cover. To maintain the liquid cooling cabinet or any of the IT devices, the maintenance personnel have to open the upper cover of the liquid cooling cabinet. In this case, the gaseous coolant tends to be volatilized into the air, resulting in loss of the gaseous coolant and even environmental pollution or health risks to the maintenance personnel.

### SUMMARY

The present application provides a liquid cooling cabinet which can solve the problems of loss of a gaseous coolant, environmental pollution, or impact on the health of the maintenance personnel caused by the gaseous coolant volatilized from the inside of the cabinet body to the external environment during maintenance by the maintenance personnel.

The present application provides a liquid cooling cabinet, comprising:
a cabinet body including an accommodating space having an opening, and further including a bottom plate and side plates, where the opening corresponds to the bottom plate, and the bottom plate is provided with a liquid inlet pipe;
an independent compartment in the accommodating space, where the independent compartment has a device accommodating cavity; and
a connector in communication with the liquid inlet pipe and the device accommodating cavity, where the connector is located in the accommodating space, the connector includes a first connecting member and a second connecting member, the first connecting member is disposed in the liquid inlet pipe, the second connecting member is disposed in the independent compartment, and the first connecting member is detachably connected to the second connecting member.

According to the liquid cooling cabinet of the present application, the independent compartment may be used for housing an IT device. When the first connecting member is connected to the second connecting member, the coolant liquid can flow through the first connecting member and the second connecting member via the liquid inlet pipe, and enter an interior of the independent compartment. The IT device can be completely immersed into the coolant liquid, so that heat generated during operation of the IT device can be led out to achieve heat dissipation and cooling of the IT device, thereby favorably reducing the possibility of a higher temperature of the IT device in operation, which may otherwise reduce the operating performance of the device.

A gaseous coolant tends to be generated while heat dissipation and cooling of the IT device are implemented by the coolant liquid. The gaseous coolant may be located in a device accommodating cavity, so that it is not easy to be volatilized to the air from the inside of the independent compartment even if the maintenance personnel opens the cabinet body, which can favorably reduce loss of the gaseous coolant, as well as the possibility of the gaseous coolant volatilized to the external environment, causing environmental pollution or impairing health of the maintenance personnel.

According to one embodiment of the present application, the independent compartment includes a compartment body and a cover body, the compartment body is sealedly connected to the cover body, the compartment body and the cover body form the device accommodating cavity, the cover body is located on a top of the compartment body, the second connecting member is provided at a bottom of the compartment body, and the first connecting member is connected with the second connecting member in a plug-in mode in a height direction of the cabinet body.

According to one embodiment of the present application, a plurality of independent compartments are provided and arranged in parallel along a length direction of the cabinet body, and each independent compartment is connected to the liquid inlet pipe through a plurality of connectors, arranged at intervals along a width direction of the cabinet body.

According to one embodiment of the present application, the cabinet body includes two opposite side plates, and the independent compartment is slidably connected to the two opposite side plates in the height direction of the cabinet body.

According to one embodiment of the present application, the liquid cooling cabinet includes a slide rail on a surface of the side plate facing the accommodating space, where the slide rail is arranged along the height direction, the independent compartment includes a slide groove corresponding to the slide rail, the slide rail is slidable along the slide groove, and the slide rail is at least partially located in the slide groove.

According to one embodiment of the present application, the independent compartment includes a flow equalizing module inside the compartment body, the flow equalizing module is disposed corresponding to the second connecting member, and the flow equalizing module is spaced apart from the second connecting member in the height direction.

According to one embodiment of the present application, the compartment body includes two opposite side walls in the width direction, the independent compartment further includes a liquid outlet joint and a gas outlet joint provided on the two side walls, respectively, and in the height direction, the liquid outlet joint and the gas outlet joint are disposed adjacent to the cover body, and the gas outlet joint has a higher height than the liquid outlet joint.

According to one embodiment of the present application, the liquid cooling cabinet includes a liquid outlet pipe, a liquid outlet collector and a first liquid sump, the liquid outlet pipe, the liquid outlet collector and the first liquid sump are provided inside the cabinet body, and the first liquid sump is correspondingly disposed below the liquid outlet joint, the liquid outlet pipe and the liquid outlet collector in the height direction; and
the liquid cooling cabinet further includes a gas outlet pipe, a gas outlet collector and a second liquid sump, the gas outlet joint, the gas outlet pipe and the gas outlet collector are provided inside the cabinet body, and the second liquid sump is correspondingly disposed below the gas outlet joint, the gas outlet pipe and the gas outlet collector in the height direction.

According to one embodiment of the present application, the liquid cooling cabinet includes a third liquid sump on a side of the liquid inlet pipe facing the independent compartment, and the first connecting member is located inside the third liquid sump.

According to one embodiment of the present application, the independent compartment includes a strong electricity outlet and a weak electricity outlet provided on the two side walls in the width direction, respectively.

### BRIEF DESCRIPTION OF THE DRAWINGS

The accompanying drawings, which are incorporated in and constitute a part of this specification, illustrate embodiments consistent with the present application and, together with the description, serve to explain the principles of the present application.

FIG. 1 is a partial structural view of a liquid cooling cabinet with an IT device placed therein according to an embodiment of the present application;

FIG. 2 is a partial sectional view of a liquid cooling cabinet with an IT device placed therein according to an embodiment of the present application;

FIG. 3 is an enlarged view at A in FIG. 2;

FIG. 4 is a schematic structural diagram of an independent compartment with an IT device placed therein according to an embodiment of the present application;

FIG. 5 is a partial sectional view of a liquid cooling cabinet with an IT device placed therein according to another embodiment of the present application;

FIG. 6 is an enlarged view at B in FIG. 5;

FIG. 7 is a partial sectional view of a liquid cooling cabinet according to an embodiment of the present application;

FIG. 8 is an enlarged view at C in FIG. 7;

FIG. 9 is a schematic structural diagram of an independent compartment according to an embodiment of the present application; and

FIG. 10 is a schematic structural diagram of a liquid cooling cabinet provided with a coolant distribution unit according to an embodiment of the present application.

Specific embodiments of the present application have been shown by way of example in the drawings and will be described in more detail below. The drawings and written description are not intended to limit the scope of the inventive concepts in any manner, but rather to illustrate the concepts of the present application to those skilled in the art with reference to specific embodiments.

### DETAILED DESCRIPTION

Here, exemplary embodiments will be illustrated in detail, examples of which are shown in the accompanying drawings. The following description refers to the accompanying drawings in which the same numbers in different drawings represent the same or similar elements unless otherwise indicated. The implementations described in the following exemplary embodiments do not represent all implementations consistent with the present application. Rather, they are merely examples of apparatus and methods consistent with certain aspects of the present application, as detailed in the appended claims.

A liquid cooling cabinet 10 is a cabinet for cooling an IT device 20 by liquid cooling. Common liquid cooling techniques include cold plate cooling and immersion cooling.

In the cold plate cooling, a heat-conducting plate is provided in a key heat dissipation region of the IT device 20. A flowing coolant liquid is provided inside the heat-conducting plate so that the coolant liquid can take heat in the key heat dissipation region of the IT device 20 out to achieve the effect of heat dissipation and cooling. The key heat dissipation region refers to a region where a large amount of heat is generated during operation of the IT device 20. The key heat dissipation region is a local region.

In the immersion cooling, the entire IT device 20 may be completely immersed into the coolant liquid. The coolant liquid can absorb heat generated during operation of the IT device 20 to reduce heat in the IT device 20.

The coolant liquid is insulative and non-conductive, and has relatively good heat dissipation. Illustratively, the coolant liquid may be a fluorinert.

The liquid cooling cabinet 10 of the present disclosure can achieve heat dissipation and cooling of the IT device 20 by immersion cooling. In the existing art, a plurality of IT devices 20 are all placed inside the liquid cooling cabinet. Each IT device 20 can be completely immersed into the coolant liquid. The liquid cooling cabinet is typically configured with an upper cover. During heat dissipation and cooling of the IT devices 20 by the coolant liquid, a gaseous coolant is present between a level of the coolant liquid in the liquid cooling cabinet and the upper cover. To maintain the liquid cooling cabinet or any of the IT devices 20, the maintenance personnel have to open the upper cover of the liquid cooling cabinet. In this case, the gaseous coolant tends to be volatilized into the air, resulting in loss of the gaseous coolant and even environmental pollution or health risks to the maintenance personnel.

In view of the above problems, the applicant improves the structure of the liquid cooling cabinet 10, and the following further describes embodiments of the present application.

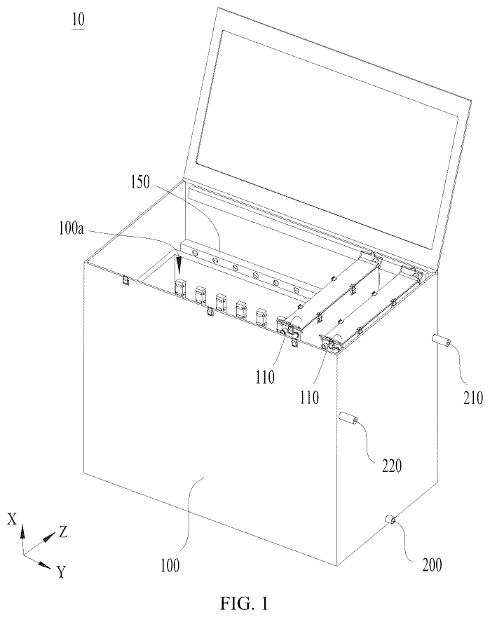

Referring to FIGS. 1 to 3, the liquid cooling cabinet 10 provided in the embodiment of the present application includes a cabinet body 100, an independent compartment 110, and a connector 120.

The cabinet body 100 includes an accommodating space 100a having an opening. The cabinet body 100 further includes a bottom plate 101 and side plates 102. The opening corresponds to the bottom plate 101, and the bottom plate 101 is provided with a liquid inlet pipe 103. The independent compartment 110 is located in the accommodating space 100a. The independent compartment 110 has a device accommodating cavity 110a. The connector 120 is in communication with the liquid inlet pipe 103 and the device accommodating cavity 110a. The connector 120 is located in the accommodating space 100a. The connector 120 includes a first connecting member 121 and a second connecting member 122. The first connecting member 121 is disposed in the liquid inlet pipe 103. The second connecting member 122 is disposed in the independent compartment 110. The first connecting member 121 is detachably connected to the second connecting member 122.

The independent compartment 110 of the present application may be used for housing an IT device 20. When the first connecting member 121 is connected to the second connecting member 122, the coolant liquid can flow through the first connecting member 121 and the second connecting member 122 via the liquid inlet pipe 103, and enter an interior of the independent compartment 110. The IT device 20 can be completely immersed into the coolant liquid, so that heat generated during operation of the IT device 20 can be led out to achieve heat dissipation and cooling of the IT device 20, thereby favorably reducing the possibility of a higher temperature of the IT device 20 in operation, which may otherwise reduce the operating performance of the device.

A gaseous coolant tends to be generated while heat dissipation and cooling of the IT device 20 are implemented by the coolant liquid. The gaseous coolant may be located in a device accommodating cavity 110a, so that it is not easy to be volatilized to the air from the inside of the independent compartment 110 even if the maintenance personnel opens the cabinet body 100, which can favorably reduce loss of the gaseous coolant, as well as the possibility of the gaseous coolant volatilized to the external environment, causing environmental pollution or impairing health of the maintenance personnel.

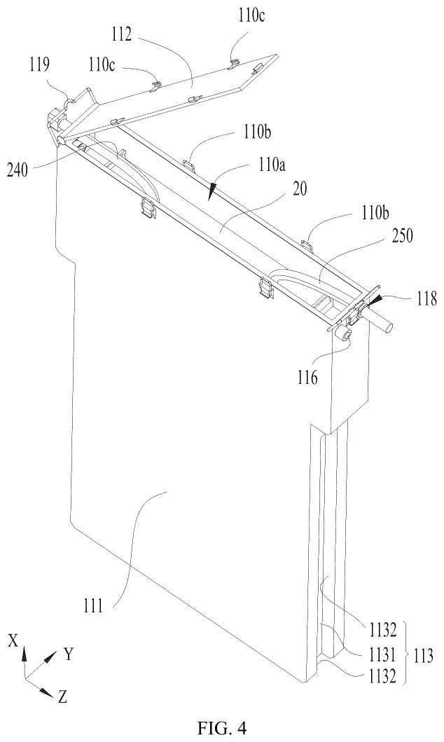

In some possible implementations, referring to FIG. 4, the independent compartment 110 provided in the embodiment of the present application includes a compartment body 111 and a cover body 112. The compartment body 111 is sealedly connected to the cover body 112. The compartment body 111 and the cover body 112 form the device accommodating cavity 110a. The cover body 112 is located on a top of the compartment body 111. The second connecting member 122 is provided at a bottom of the compartment body 111. The first connecting member 121 is connected with the second connecting member 122 in a plug-in mode in a height direction X of the cabinet body 100.

The compartment body 111 and the cover body 112 provided in the embodiment of the present application may be sealedly connected to form a sealed device accommodating cavity 110a, so that the possibility of volatilization of the gaseous coolant caused by the maintenance personnel opening the cabinet body 100 can be reduced.

In some examples, since the compartment body 111 is sealedly connected to the cover body 112, the gaseous coolant is not easy to be volatilized to the air from the independent compartment 110 even if the maintenance personnel opens the cabinet body 100. Therefore, no additional sealing structure is desired for the cabinet body 100 of the liquid cooling cabinet 10, and even the upper cover for closing the cabinet body 100 can be omitted, thereby facilitating reduction in the processing cost of the liquid cooling cabinet 10.

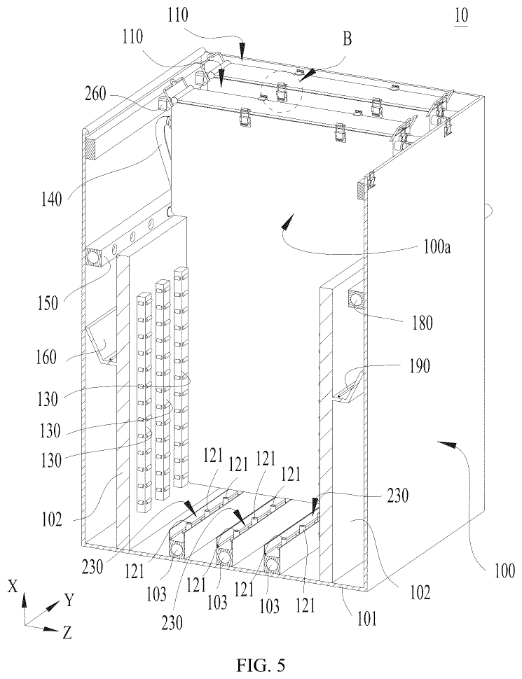

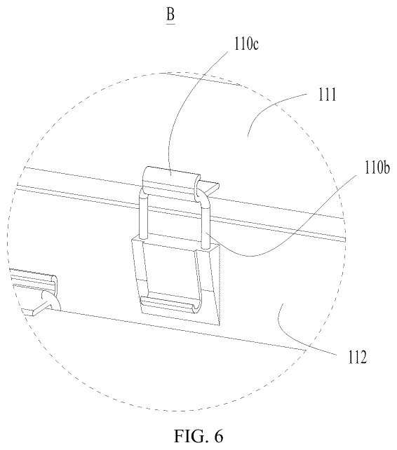

In some examples, referring to FIGS. 5 and 6, the compartment body 111 is provided with an opening on one end. The cover body 112 may be configured to cover the opening. Illustratively, the compartment body 111 may be connected to the cover body 112 by snapping. Illustratively, the compartment body 111 is provided with an engagement part 110b. The cover body 112 is provided with a clamping part 110c. When the engagement part 110c is engaged with the clamping part 110b, the cover body 112 can cover and close the compartment body 111 to seal the device accommodating cavity 110a.

In some examples, a seal ring may be provided between the compartment body 111 and the cover body 112 in the height direction X. When the engagement part 110c is engaged with the clamping part 110b, the cover body 112 can compress the seal ring so that the sealing effect of the device accommodating cavity 110a can be improved.

In some examples, the cover body 112 may have a transparent structure, and the maintenance personnel may observe operation conditions of the IT device 20 inside through the cover body 112 of the transparent structure.

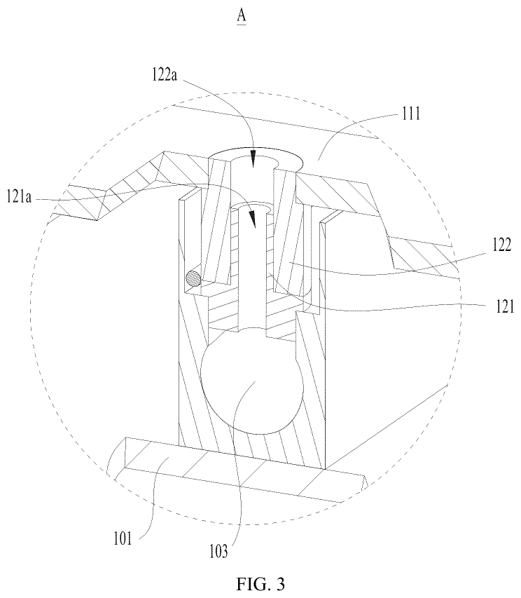

In some examples, referring to FIG. 3, the first connecting member 121 may include a cylindrical plug. The cylindrical plug may include a first through hole 121a. The second connecting member 122 may include a cylindrical socket. The cylindrical socket may include a second through hole 122a. In the height direction X, the cylindrical plug may face upward, and the cylindrical socket may face downward. The cylindrical plug may be provided corresponding to the cylindrical socket, so that when the maintenance personnel places the independent compartment 110 into the accommodating space 100a, the cylindrical plug can be easily inserted into the cylindrical socket, thereby improving the maintenance efficiency.

In some examples, the cylindrical plug may be at least partially inserted into the second through hole 122a in the height direction X. The first through hole 121a and the second through hole 122a may be provided in the height direction X, and the liquid inlet pipe 103, the first through hole 121a, the second through hole 122a, and the device accommodating cavity 110a of the independent compartment 110 may be communicated with each other. The coolant liquid in the liquid inlet pipe 103 may flow through the first through hole 121a and the second through hole 122a to get into the device accommodating cavity 110a.

In some possible implementations, referring to FIG. 5, a plurality of independent compartments 110 are provided in the embodiment of the present application. The plurality of independent compartments 110 are arranged in parallel along a length direction Y of the cabinet body 100. Each independent compartment 110 is connected to the liquid inlet pipe 103 through a plurality of connectors 120 arranged at intervals along a width direction Z of the cabinet body 100.

Each independent compartment 110 provided in the embodiment of the present application may be provided with an IT device 20 therein. The liquid cooling cabinet 10 may house a plurality of independent compartments 110. It should be noted that the coolant liquid cannot be communicated among the plurality of independent compartments 110. When any of the independent compartment 110 is placed into the accommodating space 100a, the first connecting member 121 is connected to the second connecting member 122, and then the coolant liquid can flow through the first connecting member 121 and the second connecting member 122 via the liquid inlet pipe 103, and enter an interior of the independent compartment 110 to implement heat dissipation and cooling of the IT devices 20. To maintain the IT device 20 in any one of the independent compartments 110, the independent compartment 110 may be taken out of the accommodating space 100a, and then, the second connecting member 122 of the independent compartment 110 is disconnected from the corresponding first connecting member 121 so that the coolant liquid in the liquid inlet pipe 103 will not be further introduced into the independent compartment 110, which reduces consumption of the coolant liquid and facilitates reduction in the cost of the liquid cooling cabinet 10 on one hand, and will not affect normal operation of the other IT devices 20 on the other hand.

In some examples, the independent compartments 110 may be uniformly arranged in the accommodating space 100a, so that more independent compartments 110 can be provided in the limited accommodating space 100a, thereby enabling cooling of more IT devices 20. Meanwhile, the coolant liquid only needs to be provided inside each independent compartment 110, so that the best use of the coolant liquid can be achieved, and the usage amount of the coolant liquid can be saved.

In some examples, referring to FIG. 5, the plurality of independent compartments 110 may be arranged in parallel along a length direction Y. Further, in a width direction Z, each independent compartment 110 may be connected to the cabinet body 100 via three connectors 120. Accordingly, also three liquid inlet pipes 103 may be provided. Each liquid inlet pipe 103 may extend in the length direction Y.

In some examples, the independent compartment 110 may be sized according to a size of the IT device 20. The accommodating space 100a may house a plurality of independent compartments 110 of different sizes, so that cooling of various different IT devices 20 can be implemented.

In some possible implementations, referring to FIG. 5, the cabinet body 100 provided in the embodiment of the present application includes two opposite side plates 102. The independent compartment 110 is slidably connected to the two opposite side plates 102 in the height direction X of the cabinet body 100.

The independent compartment 110 provided in the embodiment of the present application may slide into the accommodating space 100a through the opening, so that the maintenance personnel can conveniently disassemble and assemble the independent compartment 110.

In some examples, the plurality of independent compartments 110 may be arranged in parallel along a length direction Y, so that both sides of each independent compartment 110 in the width direction Z can be slidably connected to the two side plates 102.

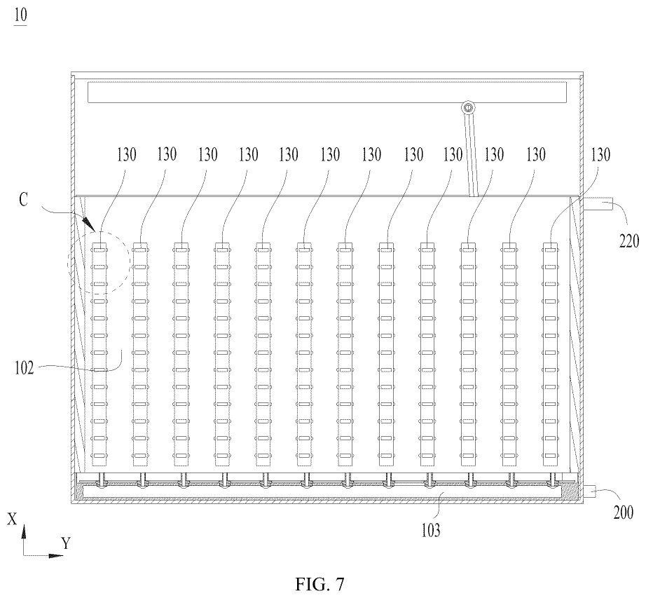

In some possible implementations, referring to FIGS. 5 and 7, the liquid cooling cabinet 10 provided in the embodiment of the present application includes a slide rail 130. The slide rail 130 is disposed on a surface of each side plate 102 facing the accommodating space 100a. The slide rail 130 is arranged along the height direction X. The independent compartment 110 includes a slide groove 113. The slide groove 113 is disposed corresponding to the slide rail 130. The slide rail 130 may be slidable along the slide groove 113. The slide rail 130 is at least partially located in the slide groove 113.

The slide groove 113 provided in the embodiment of the present application has a guiding function. The slide groove 113 may be arranged along the height direction X. The slide groove 113 may be provided on an outer surface of the compartment body 111 and recessed toward the device accommodating cavity 110a. The slide rail 130 may be slidable along the slide groove 113, so that the independent compartment 110 can slide down vertically along the height direction X. Therefore, on one hand, the possibility of the independent compartment 110 deflecting in a horizontal direction and making it difficult to align the second connecting member 122 and the first connecting member 121 can be reduced; and on the other hand, when a plurality of independent compartments 110 are provided in the liquid cooling cabinet 10, the possibility of one of the independent compartments 110 being obliquely installed in the accommodating space 100a and taking space of other independent compartments 110, and thereby causing unreasonable use of the accommodating space 100a can be reduced.

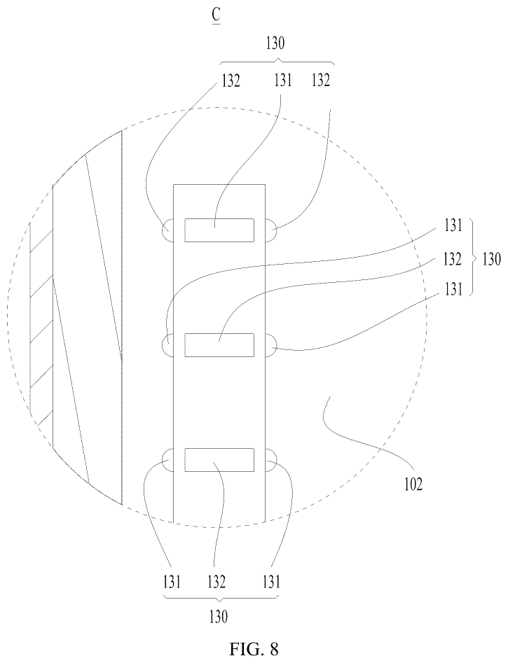

In some examples, referring to FIGS. 4 and 8, the slide rail 130 may include a first roller 131 and a second roller 132. An axis of the first roller 131 may be intersected with an axis of the second roller 132. In the length direction Y, the first roller 131 may be provided with the second roller 132 on two sides, respectively. The slide groove 113 may include a bottom wall 1131 and two inner walls 1132. The two inner walls 1132 are disposed oppositely in the length direction Y. The bottom wall 1131 may be disposed facing the corresponding side plate 102. The first roller 131 is slidably connected to the bottom wall 1131. The second roller 132 is slidably connected to the inner walls 1132.

Illustratively, a plurality of first rollers 131 and a plurality of second rollers 132 may be provided. The plurality of first rollers 131 may be disposed at intervals in the height direction X. The plurality of second rollers 132 may also be disposed at intervals in the height direction X.

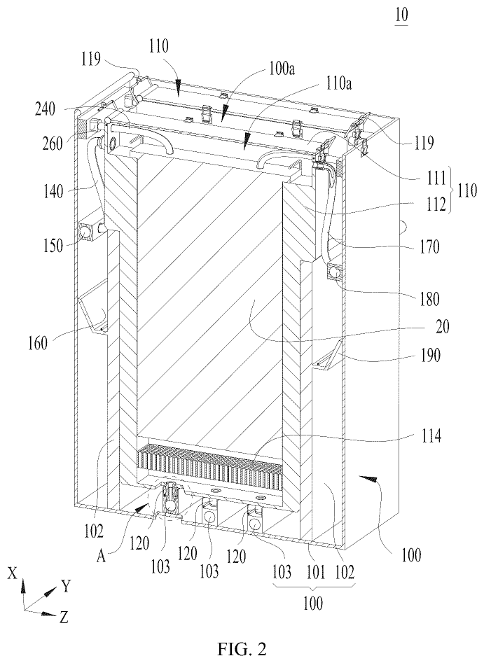

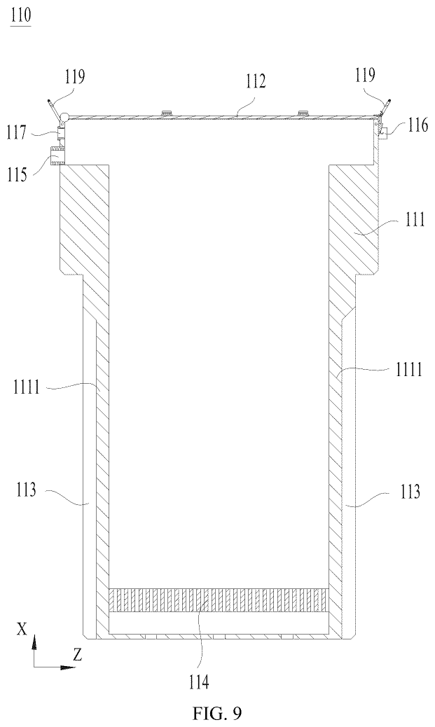

In some possible implementations, referring to FIGS. 2 and 9, the independent compartment 110 provided in the embodiment of the present application includes a flow equalizing module 114. The flow equalizing module 114 is located inside the compartment body 111. The flow equalizing module 114 is disposed corresponding to the second connecting member 122. The flow equalizing module 114 is spaced apart from the second connecting member 122 in the height direction X.

In the height direction X, after passing through the flow equalizing module 114, the coolant liquid that enters a bottom of the independent compartment 110 through the second connecting member 122 can gradually flow upward and cover the IT device 20 uniformly to ensure uniform contact between the coolant liquid and the IT device 20, which can reduce the possibility of non-uniform contact between the IT device 20 and the coolant liquid that may affect the cooling effect of the IT device 20.

In some examples, when the IT device 20 is placed inside the independent compartment 110, a bottom end of the IT device 20 is spaced apart from the flow equalizing module 114 in the height direction X.

In some examples, a plurality of through holes are provided in the flow equalizing module 114 uniformly.

In some possible implementations, referring to FIG. 9, the compartment body 111 includes two opposite side walls 1111. The independent compartment 110 further includes a liquid outlet 210 joint 115 and a gas outlet joint 116. The liquid outlet 210 joint 115 and the gas outlet joint 116 are disposed on the two side walls 1111, respectively. In the height direction X, the liquid outlet 210 joint 115 and the gas outlet joint 116 are disposed adjacent to the cover body 112. The gas outlet joint 116 has a higher height than the liquid outlet joint 115.

The connector 120 provided in the embodiment of the present application may be located at a bottom of the independent compartment 110. The coolant liquid may enter an interior of the independent compartment 110 through the connector 120. It should be noted that the coolant liquid entering the independent compartment 110 through the connector 120 is at a lower temperature. In the height direction X, the coolant liquid of lower temperature may gradually flow upward and absorb heat generated during operation of the IT device 20. After absorbing the heat, the coolant liquid of lower temperature has an increased temperature. When the temperature of the coolant liquid reaches a preset value, the coolant liquid may be discharged through a joint of the liquid outlet 210. It should be noted that the coolant liquid discharged through the liquid outlet 210 is at a higher temperature. Meanwhile, the liquid inlet pipe 103 may introduce further coolant liquid of lower temperature into the independent compartment 110 through the connector 120, and then, the coolant liquid is further circulated in this manner, thereby implementing cooling of the IT device 20 during operation.

After absorbing the heat, the coolant liquid of lower temperature has an increased temperature, and part of the coolant liquid is converted into gaseous coolant. When reaching a saturated state, the gaseous coolant may be discharged through the gas outlet joint 116.

In the embodiment of the present application, the gas outlet joint 116 may have a higher height than the liquid outlet joint 115, so that the possibility of the coolant liquid being discharged through the gas outlet joint 116 can be reduced.

In some examples, the coolant liquid entering through the connector 120 may have the same flow rate as the coolant liquid discharged from the liquid outlet joint 115, thereby ensuring a stable level of the coolant liquid in the independent compartment 110, and improving stability of the cooling effect of the coolant liquid on the IT device 20.

In some examples, the independent compartment 110 may be provided with a safety gas valve. If the saturated gaseous coolant in the independent compartment 110 is not discharged through the gas outlet joint 116 in time, a gas pressure in the independent compartment 110 will gradually increase. The safety gas valve can maintain stable gas pressures both inside and outside the independent compartment 110, and reduce the possibility of a failure of the liquid cooling cabinet 10 caused by a high pressure in the independent compartment 110.

In some examples, in the width direction Z and as shown in FIG. 9, the cover body 112 of the independent compartment 110 may be provided with a lifting lug 119. The lifting lug 119 may be used to lift the independent compartment 110. To maintain the independent compartment 110, the independent compartment 110 may be firstly lifted by the lifting lug 119 and then inverted, and then the coolant liquid in the independent compartment 110 may be pumped out through the liquid outlet joint 115. At this time, the safety gas valve can reduce the possibility of deformation of the independent compartment 110 due to the fact that an internal gas pressure of the independent compartment 110 is lower than an external gas pressure when the coolant liquid is pumped out too much.

In some possible implementations, referring to FIGS. 2 and 5, the liquid cooling cabinet 10 includes a liquid outlet pipe 140, a liquid outlet collector 150, and a first liquid sump 160. The liquid outlet pipe 140, the liquid outlet collector 150 and the first liquid sump 160 are located inside the cabinet body 100. The first liquid sump 160 is correspondingly disposed below the liquid outlet joint 115, the liquid outlet pipe 140 and the liquid outlet collector 150 in the height direction X.

In some examples, the liquid outlet joint 115 and the liquid outlet pipe 140 may be connected at a first connection. The liquid outlet pipe 140 and the liquid outlet collector 150 may be connected at a second connection. The first liquid sump 160 may be correspondingly disposed below the first connection and the second connection, so that any coolant liquid leaked out from the first or second connection can fall into the first liquid sump 160 below. Therefore, the maintenance personnel can clean the leaked coolant liquid conveniently, and a clean and tidy internal environment of the liquid cooling cabinet 10 is guaranteed.

In some examples, a liquid leakage sensor may be provided on a surface of the first liquid sump 160 facing the first connection and the second connection. When there is any coolant liquid falling into the first liquid sump 160, the liquid leakage sensor may send an indication signal to prompt the maintenance personnel to check a cause of the liquid leakage in time, thereby reducing loss of the coolant liquid.

In some possible implementations, referring to FIGS. 2 and 5, the liquid cooling cabinet 10 further includes a gas outlet pipe 170, a gas outlet collector 180 and a second liquid sump 190, and the gas outlet joint 116, the gas outlet pipe 170 and the gas outlet collector 180 are provided inside the cabinet body 100. The second liquid sump 190 is correspondingly disposed below the gas outlet joint 116, the gas outlet pipe 170 and the gas outlet collector 180 in the height direction X.

In some examples, the gas outlet joint 116 and the gas outlet pipe 170 may be connected at a third connection. The gas outlet pipe 170 and the gas outlet collector 180 may be connected at a fourth connection. While the gaseous coolant is discharged through a gas outlet port, it is also possible that some coolant liquid may also be discharged through the gas outlet port. The second liquid sump 190 may be correspondingly disposed below the third connection and the fourth connection, so that any coolant liquid leaked out from the third or fourth connection can fall into the second liquid sump 190. Therefore, the maintenance personnel can clean the leaked coolant liquid conveniently, and a clean and tidy internal environment of the liquid cooling cabinet 10 is guaranteed.

In some examples, a liquid leakage sensor may be also provided on a surface of the second liquid sump 190 facing the third connection and the fourth connection. When there is any coolant liquid falling into the second liquid sump 190, the liquid leakage sensor may send an indication signal to prompt the maintenance personnel to check a cause of the liquid leakage in time, thereby reducing loss of the coolant liquid.

In some examples, the first liquid sump 160 may be in communication with the second liquid sump 190.

In some examples, the side plates 102 of the liquid cooling cabinet 10 may be provided with a liquid inlet 200, a liquid outlet 210, and a gas pumping port 220, and the liquid inlet 200, the liquid outlet 210, and the gas pumping port 220 may be located on the same side plate 102. The liquid inlet 200 is in communication with the liquid inlet pipe 103. The liquid outlet 210 is connected to the liquid outlet collector 150. The gas pumping port 220 is connected to the gas outlet collector 180.

To sum up, the liquid cooling cabinet 10 provided the embodiment of the present application is operated based on the following principles: A coolant liquid of lower temperature flows through the liquid inlet pipe 103 and the connector 120 via the liquid inlet 200, and into an interior of the independent compartment 110. In the height direction X, the coolant liquid of lower temperature gradually flows upward to absorb heat generated by the IT device 20. After absorbing the heat, the coolant liquid of lower temperature has a gradually increased temperature. When the temperature of the coolant liquid reaches a preset value, the coolant liquid of higher temperature may flow through the liquid outlet pipe 140 via the liquid outlet joint 115, into the liquid outlet collector 150, and finally flow out of the liquid cooling cabinet 10 via the liquid outlet 210.

Meanwhile, the coolant liquid can generate gaseous coolant after absorbing heat. When saturated, the gaseous coolant may pass through the gas outlet pipe 170 via the gas outlet joint 116, into the gas outlet collector 180, and finally get out of the liquid cooling cabinet 10 via the gas pumping port 220.

In some possible implementations, referring to FIG. 5, the liquid cooling cabinet 10 includes a third liquid sump 230. The third liquid sump 230 is provided on a side of the liquid inlet pipe 103 facing the independent compartment 110. The first connecting member 121 is located inside the third liquid sump 230.

The third liquid sump 230 provided in the embodiment of the present application may be configured to house the coolant liquid leaked between the first connecting member 121 and the second connecting member 122. Therefore, the maintenance personnel can clean the leaked coolant liquid conveniently, and a clean and tidy internal environment of the liquid cooling cabinet 10 is guaranteed.

In some examples, the third liquid sump 230 is arranged along the length direction Y. The third liquid sump 230 is disposed corresponding to the liquid inlet pipe 103. Illustratively, the number (for example, three) of third liquid sumps 230 is the same as the number of liquid inlet pipes 103.

In some examples, a liquid leakage sensor may be provided on the third liquid sump 230. The liquid leakage sensor may send an indication signal to prompt the maintenance personnel to check a cause of the liquid leakage in time, thereby reducing loss of the coolant liquid.

In some possible implementations, referring to FIGS. 5 and 9, the independent compartment 110 includes a strong electricity outlet 117 and a weak electricity outlet 118. The strong electricity outlet 117 and the weak electricity outlet 118 are provided on the two side walls 1111 in the width direction Z, respectively.

In the height direction X, a strong electricity cable 240 and a weak electricity cable 250 may be provided on a top of the IT device 20. The strong electricity cable 240 may be spaced apart from the weak electricity cable 250 in the width direction Z. The liquid cooling cabinet 10 includes a power distribution unit (PDU) 260. The PDU 260 has a power distribution and management function. The strong electricity cable 240 may be connected to the PDU 260 in the liquid cooling cabinet 10 through the strong electricity outlet 117. The weak electricity cable 250 may pass through the weak electricity outlet 118 to extend out of the independent compartment 110.

In some examples, strong electricity cables 240 of a plurality of IT devices 20 may be all plugged into the PDU 260.

In some examples, the strong electricity outlet 117 and the liquid outlet joint 115 may be disposed on the same side plate 102. In the height direction X, the strong electricity outlet 117 may have a higher height than the liquid outlet joint 115, so that the possibility of wetting the strong electricity cable 240 by the coolant liquid leaked from a liquid outlet joint 115 that is located above the strong electricity outlet 117 can be reduced.

In some examples, the weak electricity outlet 118 and the gas outlet joint 116 may be disposed on the same side plate 102.

In some examples, the liquid cooling cabinet 10 may further include a weak electricity wire slot. The weak electricity wire slot may be configured to manage a plurality of weak electricity cables 250 extending out of a plurality of independent compartments 110. The weak electricity wire slot may be disposed corresponding to the weak electricity outlet 118.

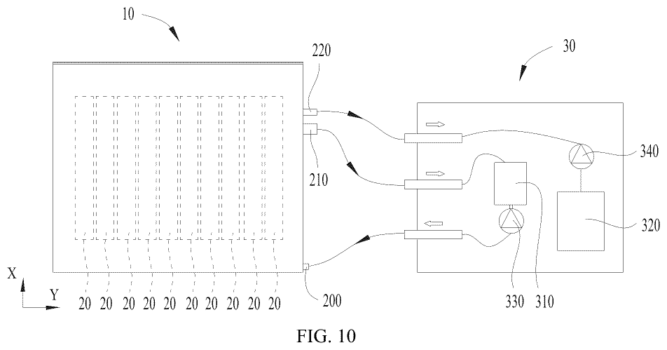

In some possible implementations, referring to FIG. 10, the liquid cooling cabinet 10 of the present application may be provided with a coolant distribution unit (CDU) 30. The CDU 30 may be configured to regulate a temperature of the coolant liquid. The CDU 30 may be disposed side by side with the liquid cooling cabinet 10. The CDU 30 may include a heat exchanger 310 and a gas collection container 320.

In some examples, the heat exchanger 310 may have one end connected to the liquid outlet 210, and the other end connected to the liquid inlet 200. After passing through the heat exchanger 310, the coolant liquid of higher temperature flowing out of the liquid outlet 210 can be converted into coolant liquid of lower temperature, and flow into the independent compartment 110 through the liquid inlet 200 again to cool the IT device 20, and then be further circulated in this manner.

In some examples, the heat exchanger 310 may have one end connected to a water pump 330. The water pump 330 may be configured to deliver a coolant liquid. Illustratively, the water pump 330 may be a variable frequency pump or a magnetic pump.

In some examples, the gas collection container 320 has a sealed space. The gas collection container 320 may be connected to the gas pumping port 220. The gas collection container 320 may be configured to collect the gaseous coolant for centralized processing, so that the possibility of the gaseous coolant volatilized to the surrounding air, causing environmental pollution or impairing health of the maintenance personnel is reduced.

In some examples, a vacuum pump 340 may be provided between the gas collection container 320 and the gas pumping port 220. The vacuum pump 340 may be configured to pump the gaseous coolant from the independent compartment 110, and transfer the gaseous coolant to the gas collection container 320.

In the description of the embodiments of the present application, it should be noted that unless otherwise explicitly stated or limited, the terms “mounted”, “connected”, and “coupled” are to be construed broadly and may include, for example, fixed connection, indirect connection via an intermedium, internal communication between two elements, or interaction between two elements. The specific meaning of the above terms in the embodiments of the present application will be understood by those of ordinary skill in the art as the case may be.

Reference throughout this specification to apparatus or elements which are described or suggested in the embodiments of the present application as having a particular orientation, or configured and operated in a particular orientation, should not be constructed as limitations to the embodiments of the present application. In the description of the embodiments of the present application, the term “a plurality of” means two or more unless explicitly defined otherwise.

The terms “first”, “second”, “third”, “fourth”, and the like in the description and claims of the present application and in the drawings described above, if any, are used for distinguishing between similar objects and not necessarily for describing a particular sequential or chronological order. It will be appreciated that the data so used may be interchanged under appropriate circumstances such that embodiments of the present application described here can be implemented, for example, in sequences other than those illustrated or described herein.

Moreover, the terms “comprise”, “include”, and “have”, and any variations thereof, are intended to cover a non-exclusive inclusion, such that a process, method, system, article, or apparatus that includes a list of steps or units is not necessarily limited to those steps or units expressly listed, but may include other steps or units not expressly listed or inherent to such a process, method, article, or apparatus.

The term “plurality” herein refers to two or more. The term “and/or” as used herein is merely to describe an association relationship of associated objects, which may include three relationships; for example, A and/or B may refer to: A alone, both A and B, or B alone. In addition, the character “/” herein generally indicates that the former and latter associated objects are in an “or” relationship; in the formula, the character “/” indicates that the former and latter related objects are in a “division” relationship.

It should be understood that the various numerical references referred to in the embodiments of the present application are merely for convenience of description and distinction, and are not intended to limit the scope of the embodiments of the present application.

It should be understood that, in the embodiments of the present application, the sequence numbers of the above processes do not imply an order of execution, and the order of execution of the processes should be determined by their functions and inherent logic, and should not limit the implementation process of the embodiments of the present application in any way.

1. A liquid cooling cabinet comprising:
a cabinet body including an accommodating space having an opening, and further including a bottom plate and side plates, wherein the opening corresponds to the bottom plate, and the bottom plate is provided with a liquid inlet pipe;
an independent compartment in the accommodating space, wherein the independent compartment has a device accommodating cavity; and
a connector in communication with the liquid inlet pipe and the device accommodating cavity, wherein the connector is located in the accommodating space, the connector includes a first connecting member and a second connecting member, the first connecting member is disposed in the liquid inlet pipe, the second connecting member is disposed in the independent compartment, and the first connecting member is detachably connected to the second connecting member.

2. The liquid cooling cabinet of claim 1, wherein the independent compartment includes a compartment body and a cover body, the compartment body is sealedly connected to the cover body, the compartment body and the cover body form the device accommodating cavity, the cover body is located on a top of the compartment body, the second connecting member is provided at a bottom of the compartment body, and the first connecting member is connected with the second connecting member in a plug-in mode in a height direction of the cabinet body.

3. The liquid cooling cabinet of claim 2, wherein a plurality of independent compartments are provided and arranged in parallel along a length direction of the cabinet body, and each independent compartment is connected to the liquid inlet pipe through a plurality of said connectors arranged at intervals along a width direction of the cabinet body.

4. The liquid cooling cabinet of claim 3, wherein the cabinet body includes two opposite side plates, and the independent compartment is slidably connected to the two opposite side plates in the height direction of the cabinet body.

5. The liquid cooling cabinet of claim 4, wherein the liquid cooling cabinet includes a slide rail on a surface of the side plate facing the accommodating space, wherein the slide rail is arranged along the height direction, the independent compartment includes a slide groove corresponding to the slide rail, the slide rail is slidable along the slide groove, and the slide rail is at least partially located in the slide groove.

6. The liquid cooling cabinet of claim 5, wherein the independent compartment includes a flow equalizing module inside the compartment body, the flow equalizing module is disposed corresponding to the second connecting member, and the flow equalizing module is spaced apart from the second connecting member in the height direction.

7. The liquid cooling cabinet of claim 6, wherein the compartment body includes two opposite side walls in the width direction, the independent compartment further includes a liquid outlet joint and a gas outlet joint provided on the two side walls, respectively, and in the height direction, the liquid outlet joint and the gas outlet joint are disposed adjacent to the cover body, and the gas outlet joint has a higher height than the liquid outlet joint.

8. The liquid cooling cabinet of claim 7, wherein the liquid cooling cabinet includes a liquid outlet pipe, a liquid outlet collector and a first liquid sump, the liquid outlet pipe, the liquid outlet collector and the first liquid sump are provided inside the cabinet body, and the first liquid sump is correspondingly disposed below the liquid outlet joint, the liquid outlet pipe and the liquid outlet collector in the height direction; and
the liquid cooling cabinet further includes a gas outlet pipe, a gas outlet collector and a second liquid sump, the gas outlet joint, the gas outlet pipe and the gas outlet collector are provided inside the cabinet body, and the second liquid sump is correspondingly disposed below the gas outlet joint, the gas outlet pipe and the gas outlet collector in the height direction.

9. The liquid cooling cabinet of claim 8, wherein the liquid cooling cabinet includes a third liquid sump on a side of the liquid inlet pipe facing the independent compartment, and the first connecting member is located inside the third liquid sump.

10. The liquid cooling cabinet of claim 9, wherein the independent compartment includes a strong electricity outlet and a weak electricity outlet provided on the two side walls in the width direction, respectively.
